(19) United States
(12) Patent Application Publication
(10) Pub. No.: US 2021/0242511 A1
(43) Pub. Date: Aug. 5, 2021

(54) OCV ESTIMATION OF VEHICLE BATTERY IN NON-EQUILIBRIUM STATE

(71) Applicant: BORDRIN NEW ENERGY VEHICLE CORPORATION, INC., ROYAL OAK, MI (US)

(72) Inventors: FOAD SAMADI, WINDSOR (CA); YONGHUA LI, ANN ARBOR, MI (US)

(21) Appl. No.: 16/776,905

(22) Filed: Jan. 30, 2020

(51) Int. Cl. H01M 10/48; G01R 31/388; H01M 2/10; G01R 31/36

(52) U.S. Cl. CPC H01M 10/482; G01R 31/388; H01M 2220/20; G01R 31/3648; H01M 2/1077; H01M 2/1083

(57) ABSTRACT

A system and method for battery management of a vehicle is provided. The battery management system may include a battery cell or pack; a contactor and a battery controller. The contactor may be connected to the battery cell or pack. The battery controller may be connected to the battery cell or pack and the contactor. The battery controller may acquire a first measurement of the battery in response to a Keyoff event after disconnection of the contactor. The battery controller may also acquire a second measurement of the battery in response to a Keyon event before connection of the contactor. The battery controller may determine an open circuit voltage (OCV) of the battery cell or pack based on the first and second measurements. For example, the acquired OCV may be used to estimate SOC of the battery and may be used to calibrate the SOC estimation algorithm or other algorithms. The battery controller may also use the acquired measurements to identify the battery model parameters.

### BACKGROUND

### 1. Field of the Invention

The present invention generally relates to determining the open circuit voltage of a battery.

### 2. Description of Related Art

The open circuit voltage (OCV) is useful in determining the state of charge (SoC) of a battery cell or battery pack, in particular lithium-ion battery cell or battery pack, for a vehicle which directly impacts many battery management system features, safety of battery operation, etc. Prior art normally depends on obtaining OCV when the underlying battery cell or battery pack reaches an equilibrium state electrically and thermally. However, it can be difficult to obtain a reliable OCV based on vehicle operation pattern and how long the battery is allowed to rest.

### SUMMARY

A system and method for battery management of a vehicle is provided. The battery management system may include a battery cell (or pack including several battery cells connected in parallel and/or series); a contactor and a battery controller. The contactor may be connected to the battery cell or pack. The battery controller may be connected to the battery cell or pack and the contactor. The battery controller may acquire at least one first measurement of the battery in response to a Keyoff event after disconnection of the contactor. (e.g. the measurement may be a series of data point with a fixed sampling rate, for example 10 ms per data point) The battery controller may also acquire at least one second measurement of the battery in response to a Keyon event before connection of the contactor. The battery controller determines an open circuit voltage (OCV) of the battery cell or pack based on the at least one first measurement and the at least one second measurement.

The battery controller may determine the OCV based on a curve fitting of the at least one first measurement and the at least one second measurement. The battery controller may acquire at least one first measurement of the battery cell or pack in response to a Keyoff event after disconnection of the contactor and acquire at least one second measurement of the battery in response to a Keyon event before connection of the contactor. The battery controller may determine whether the battery rest time between an end of the at least one first measurement to an end of the at least one second measurement is sufficient to predict the OCV of the battery cell or pack. The battery controller may determine whether a number of collected data points are sufficient to perform a fitting of obtained voltage terminal profile while contactor was off. Further, the battery controller may determine if the temperature difference between collection of first and second measurements is in the range that allows for OCV estimation. The battery controller may perform a curve fitting algorithm of the at least one first measurement and the at least one second measurement.

The battery controller may determine the OCV if contactor remains off for a time period using the fitting equation achieved. The battery controller may also estimate SOC based on the acquired OCV. The battery controller may utilize SOC as the initial SOC to calibrate SOC estimation algorithm and other battery state estimation algorithms. The battery controller may also decide whether the battery rest time is longer than sufficient to use existing method to determine OCV, if so, abandon all collected data and use existing method to obtain OCV instead.

Further objects, features, and advantages of this disclosure will become readily apparent to persons skilled in the art after a review of the following description, with reference to the drawings and claims that are appended to and form a part of this specification.

### BRIEF DESCRIPTION OF THE DRAWINGS

FIG. 1 is a block diagram of a battery management system.

FIG. 2 is a schematic view of an RC equilibrium circuit model diagram.

FIG. 3 is a graph illustrating a curve estimating the OCV from a number of data points.

FIG. 4 is a flow chart illustrating a method for the controller to determine the OCV of the battery.

### DETAILED DESCRIPTION

Many methods may be used to estimate state of charge (SoC) of the battery. Coulomb counting based techniques, model-based estimation methods using equilibrium circuit model such as Kalman filter-based techniques are possible methods. Each method has its own advantages and disadvantages and conditions under which the method is applicable. In all methods, and particularly Coulomb counting-based techniques, it is utterly important to initialize the algorithm with correct values of SoC. SoC estimation using OCV value is one of the most accurate and reliable methods used in the current art to evaluate the battery state of charge for lithium-ion batteries with non-flat SOC-OCV curves. Sufficient rest time of the battery is imperative to correct read of OCV, and hence a battery in its equilibrium state after a sufficient rest time may be required to read the accurate OCV value of the battery.

To perform coulomb counting methods or model-based techniques, it is important to be able to initialize the methods, or tune the algorithms using some reliable initial value of SoC. To acquire such value, SoC estimation based on OCV value can be one of the most reliable methods used. However, there is a condition which needs to be met before obtaining the OCV value to estimate SoC by simply measuring battery terminal voltage once, and that is the battery must be sufficiently at rest before reading OCV and use it towards SoC estimation. However, this condition might be difficult to achieve at many driving patterns particularly when the time difference between Keyoff and Keyon events is not sufficient. If the battery has not sufficiently rested (This time could be 3 hrs or more depending on battery chemistry, battery charge level, and battery temperature), accurate value of OCV cannot be captured based solely on instant battery voltage measurement and hence SoC estimation depending on an accurate initial SoC value would not be feasible. Insufficient battery rest time will lead to poor initial values for Coulomb counting method and inaccurate SoC estimation.

This disclosure provides an improvement on OCV measurement by deriving the OCV profile using some sparse data and thus greatly relax the sufficient time condition required to perform initial SoC estimation. This method exploits the data collected after disconnection of high voltage (HV) contactor and right before shutting off battery or vehicle control unit (BCU/VCU), and data collected before connecting HV bus after Keyon event after the BCU/VCU is powered up yet the high voltage connector is still closed, to estimate the OCV profile and therefore enable the algorithm to estimate actual value of OCV when even the battery is not sufficiently rested. Hence, the time required for battery rest is greatly reduced, and will let the SoC calibration algorithm to use OCV values more frequently to estimate SoC and make correction on saved values of State of Charge from last trip.

The proposed method may not impose further complications to the data collection strategy at Keyoff and Keyon and can be conducted for just a few seconds, where BCU/VCU are on yet HV contactors are not connected.

The main technology is to estimate battery open circuit voltage (OCV) using measured terminal voltage Vₜ profile when I=0, based on sparse data acquired when the battery main HV contactor is off. The Vₜ profile can generally be fit to any given profile to estimate OCV, but a 3-RC network may be used as an example to demonstrate the technical approach in this disclosure. OCV is described as follows:

OCV=Vₜ(I=0,t=∞)

When the high voltage contactor is disconnected, and no current is charged into/discharged from battery, a few data samples are collected. This is only required at the time of Keyoff for a few milli-seconds to a few seconds, and at the time of Keyon for a few milli-seconds to a few seconds. Therefore, the number of data points collected are limited. However, as our experimental simulations show, this should be sufficient to predict the OCV value if the battery has rested more than a certain amount time which is still considerably less than sufficient time to bring battery to equilibrium state.

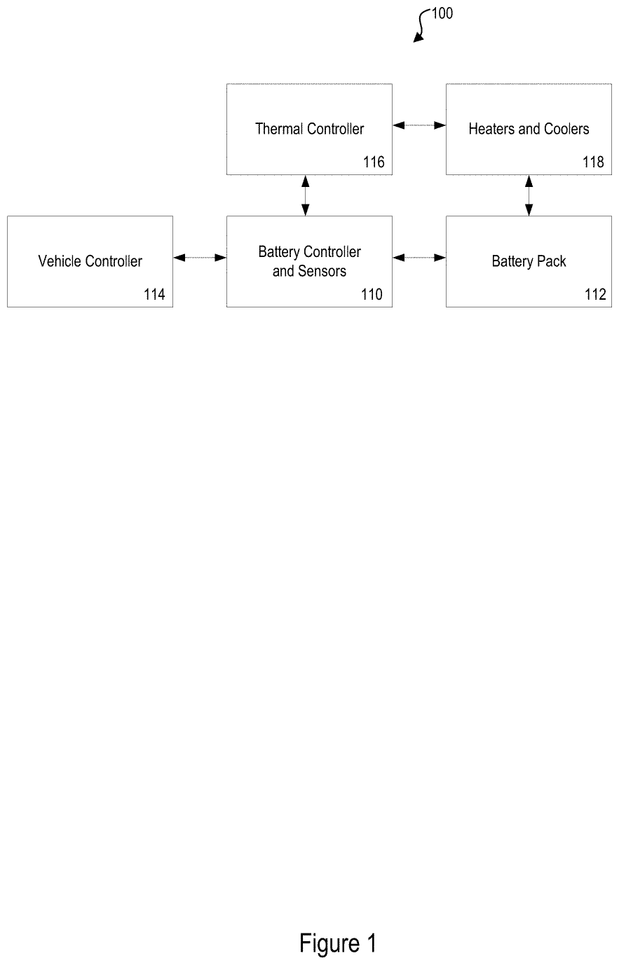

FIG. 1 is a block diagram illustrating a battery management system (BMS). The system may include a battery controller 110 and a battery cell or pack 112. The battery controller 110 may receive input from sensors that monitor battery characteristics including temperature, voltage, current, as well as other characteristics described throughout. Additionally, the battery controller 110 may connect or disconnect the battery from various components using various switches. The battery cell or pack may be configured for an electric vehicle and may be a Lithium-ion battery cell or pack or may use other battery technology. The battery controller 110 may be in communication with a vehicle controller 114 to receive vehicle information including speed, acceleration, location, distance travelled, or other parameters related to the vehicle performance from the vehicle controller 114. Additionally, the vehicle controller 114 or a network may provide the battery controller 110 access to other vehicle systems such as a global positioning system (GPS) or other subsystem to receive information that can be used to control or monitor the battery cell or pack 112.

The battery controller 110 may also be in communication with a thermal controller 116. The thermal controller 116 may heat or cool the battery cell or pack 112 using a heater or cooler 118. The heating or cooling may be based on various measured or calculated conditions of the battery cell or pack 112 and/or additional information related to the vehicle or vehicle subsystems.

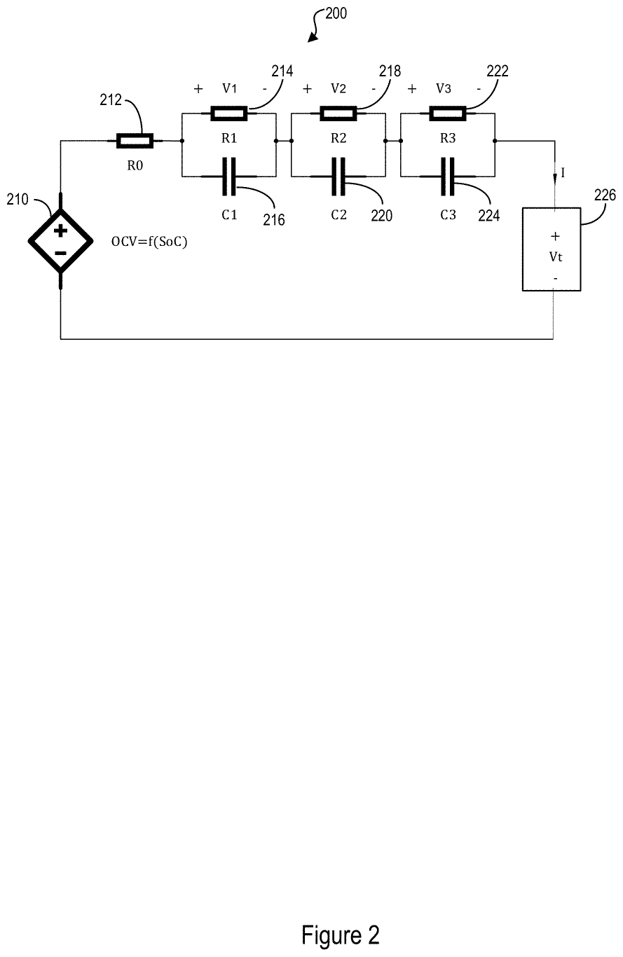

FIG. 2 is a schematic view of an RC equilibrium circuit model diagram. The battery is represented by a third-order model circuit. All model parameters R0, R1, C1, R2, C2, R3, and C3 are known battery parameters as functions of the battery temperature (and at times, SoC). The battery SOC is a nonlinear monotonic increasing function of an open-circuit voltage when the battery is in equilibrium state for each battery temperature. Such a function is represented by the characteristic SOC-OCV curves for the battery at various temperatures.

A power source 210 (e.g. battery) is provided that represents the OCV=f(SoC). The circuit 200 includes a resistance R0 represented by resistor 212. The circuit 200 includes a first load including a resistance R1 and a capacitance C1 (e.g. in parallel) that causes a voltage drop of V1 which is represented by resistor 214 and capacitor 216 (e.g. connected in parallel). The first load may be in series (e.g. or parallel not shown) with additional loads, such as a second and third load. The second load may include a resistance R2 and a capacitance C2 (e.g. in parallel) that causes a voltage drop of V2 which is represented by resistor 218 and capacitor 220 (e.g. connected in parallel). Meanwhile, the third load may include a resistance R3 and a capacitance C3 (e.g. in parallel) that causes a voltage drop of V3 which is represented by resistor 222 and capacitor 224 (e.g. connected in parallel). The loads may collectively generate a current flow of I and a total voltage drop of Vₜ which may be measured by a measurement device 226 (e.g. which may include an amp meter and/or volt meter and/or voltage sensor). The battery terminal voltage is as follows when there is no current passing through:

$${V}_{t} = OCV - {V}_{1} ( 0 ) {e}^{- \frac{t}{{τ}_{1}}} - {V}_{2} ( 0 ) {e}^{- \frac{t}{{τ}_{2}}} - {V}_{3} ( 0 ) {e}^{- \frac{t}{{τ}_{3}}}$$

$${τ}_{1} = {R}_{1} {C}_{1} , {τ}_{2} = {R}_{2} {C}_{2} , {τ}_{3} = {R}_{3} {C}_{3}$$

At the time the HV loop is disconnected, the low voltage system (BCU, VCU) may also power down. This method may provide an extra feature: at the time of low voltage power down (after the high voltage loop disconnect), the low voltage device BCU and its associated CMU (measurement devices) will be kept running for at least a calibratable amount of time, which may be temperature dependent.

This way, sufficient data points may be collected. This calibratable amount of time is normally much less than the time required for the battery to reach equilibrium state.

When data are collected, at the next Keyon event a parameter identification method is utilized to find OCV. In the above voltage profile provided based on three RC network, OCV, V₁(0), V₂(0), V₃(0) and τ₁, τ₂, and τ₃ are 7 unknown parameters to be identified.

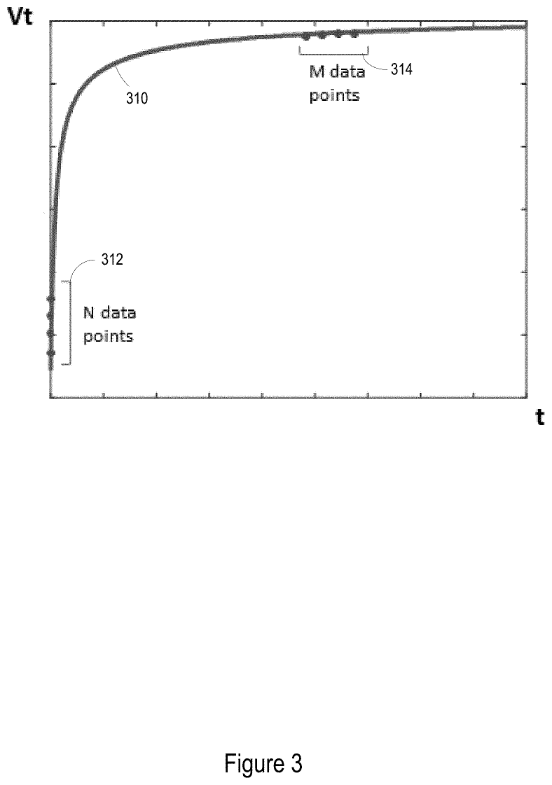

Several different curve fitting or parameter estimation algorithms can be utilized to estimate OCV. For example, regression methods, least mean square (LMS) based methods, gradient-based techniques, filtering techniques and other appropriate methods can be used to identify the unknown parameters. In this disclosure, we have employed an LMS based technique to extract OCV from collected data. In FIG. 3, Vₜ profile is illustrated when the HV loop is disconnected and I=0.

FIG. 3 is a graph illustrating a curve 310 estimating the OCV from a number of data points. The data points may include N data points 312 and M data points 314. N data points are those points that are collected at the time Keyon to Keyoff event when HV loop is disconnected. M data points represent the points collected at the time of Keyoff to Keyon event when the BCU is waken up but HV loop is not connected yet.

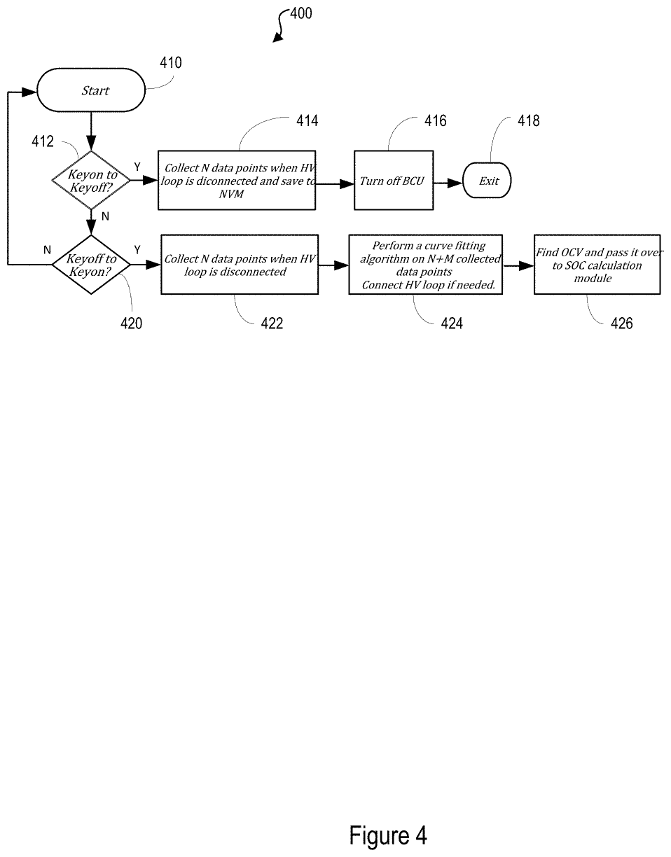

FIG. 4 is a flow chart illustrating a method for the controller to determine the OCV of the battery. The method 400 starts in block 410 and proceeds to block 412. In block 412, the controller determines if a Keyon to Keyoff event occurs. If a Keyon to Keyoff event occurs, then the method proceeds to block 414. In block 414, the controller collects N data points when the HV loop is disconnected and saves the N data points to the NVM (non-volatile memory). The method then proceeds to block 416, where the BCU is turned off. The method concludes in block 418. On the other hand, if BCU is turned on (from Keyoff to Keyon), the calculation process goes through block 420. Otherwise, if it is neither Keyon to Keyoff, or from Keyoff to Keyon, the calculation process returns to block 410.

If the controller does not detect that a Keyon to Keyoff event occurred in block 412, the method proceeds to block 420. In block 420, the controller determines if a Keyoff to Keyon event has occurred. If the controller determines that a Keyoff to Keyon event has not occurred the method may proceed to block 410 where the method starts over. If the controller detects that a Keyoff to Keyon event has occurred in block 420, then the method proceeds to block 422. In block 422, the controller may collect N data points when HV loop is disconnected. In block 424, the controller may perform a curve fitting on N and M collected data points and may connect to the HV loop if needed. The method may then proceed to block 426 where the controller may determine the OCV and may then perform additional SOC calculations based on the determined OCV. The method may then conclude or may be restarted in block 410.

A calibratable number of data points are collected after disconnecting HV contactor (at the time of Keyoff), and before connecting HV contactor (at the time of Keyon). The collected data are fit into Vₜ profile to estimate OCV of the battery using any fitting methodology (e.g. regression, polynomial, machine learning, Bayesian, Kalman filtering, etc.) that may be appropriate.

The proposed method provides a technique to estimate OCV of the battery even if the battery has not been sufficiently rested according to battery manufacturer manuals.

OCV of the battery can be estimated when the battery is not in equilibrium state. SOC of the battery can be estimated using estimated OCV with high accuracy using pre-determined SOC-OCV profile. SOC estimation algorithms can be calibrated using OCV provided by this methodology.

An extra feature of the proposed strategy of data collection when HV loop is disconnected provides the controller with extra valuable data that can help identify the battery model. In this instance, the data may be used for OCV estimation, but it can also be used for identification of other parameters of interest.

The methods, devices, units, controllers, modules, units, engines, and logic described above may be implemented in many different ways and in many different combinations of hardware and software. For example, all or parts of the implementations may be circuitry that includes an instruction processor, such as a Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may include a storage medium and instructions stored in or on the medium, and the instructions when executed by the circuitry in a device may cause the device to implement any of the processing described above or illustrated in the drawings.

The implementations may be distributed as circuitry among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

As a person skilled in the art will readily appreciate, the above description is meant as an illustration of implementation of the principles this disclosure. This description is not intended to limit the scope or application of this system in that the system is susceptible to modification, variation and change, without departing from the spirit of this disclosure, as defined in the following claims.

1. A battery management system for a vehicle comprising:
a battery cell or pack;
a contactor connected to the battery cell or pack;
a battery controller connected to the battery cell or pack and the contactor, the battery controller being configured to acquire at least one first measurement of the battery in response to a Keyoff event after disconnection of the contactor; the battery controller being further configured to acquire at least one second measurement of the battery in response to a Keyon event before connection of the contactor, the battery controller being configured to determine an open circuit voltage (OCV) of the battery cell or pack based on the at least one first measurement and the at least one second measurement.

2. The battery management system of claim 1, wherein the OCV is determined based on a curve fitting of the at least one first measurement and the at least one second measurement.

3. The battery management system of claim 1, wherein the battery controller is configured to acquire at least one first measurement of the battery cell or pack in response to a Keyoff event after disconnection of the contactor.

4. The battery management system of claim 2, wherein the battery controller is configured to acquire at least one second measurement of the battery in response to a Keyon event before connection of the contactor.

5. The battery management system of claim 2, wherein the battery controller is configured to determine whether the battery offline time between an end of the at least one first measurement to an end of the at least one second measurement is sufficient to predict the OCV profile of the battery cell or pack.

6. The battery management system of claim 5, wherein the battery controller is configured to determine whether a number of collected data points are sufficient to perform a fitting of obtained voltage terminal profile while contactor was off.

7. The battery management system of claim 4, wherein the battery controller is configured to determine if the temperature difference between collection of first and second measurements is in the range that allows for OCV estimation.

8. The battery management system of claim 4, wherein the battery controller is configured to perform a curve fitting algorithm of the at least one first measurement and the at least one second measurement.

9. The battery management system of claim 1, wherein the battery controller is configured to determine the terminal voltage if contactor remains off for a time period using the fitting equation achieved.

10. The battery management system of claim 1, wherein the battery controller is configured to estimate SOC based on acquired OCV.

11. The battery management system of claim 3, wherein the battery controller is configured to utilize SOC as the initial SOC to calibrate SOC estimation algorithm and other model-based battery state estimation algorithms.

12. A method of OCV prediction of a battery cell or pack based on data collection before power down and after power up.

13. The method according to claim 12, further comprising acquiring at least one first measurement of the battery cell or pack in response to a Keyoff event after disconnection of a contactor.

14. The method according to claim 13, further comprising acquiring at least one second measurement of the battery in response to a Keyon event before connection of the contactor.

15. The method according to claim 14, further comprising determining whether battery offline time since the end of first set of measurement to end of second measurement is sufficient to predict the OCV profile of the battery cell or pack.

16. The method according to claim 15, further comprising determining whether the number of collected data points are sufficient to perform a fitting of obtained voltage terminal profile while the contactor was off.

17. The method according to claim 16, further comprising determining whether the temperature difference between collection of first and second measurements is in a range that allows for OCV estimation.

18. The method according to claim 17, further comprising performing a curve fitting algorithm of the at least one first measurement and the at least one second measurement.

19. The method according to claim 18, further comprising determining a terminal voltage if a contactor remains off fora time period using the curve fitting equation.

20. The method according to claim 18, further comprising determining whether the battery rest time is longer than sufficient to use existing method to determine OCV.
